(19) United States
(12) Patent Application Publication
(10) Pub. No.: US 2026/0048447 A1
(43) Pub. Date: Feb. 19, 2026

(54) RADIAL MULTI-POINT SOLDER TIP AND RELATED SOLDER DEVICE

(71) Applicant: Vertiv IT Systems, Inc., Westerville, OH (US)

(72) Inventors: Christopher A. DeJesus, Huntsville, AL (US); Mark Barnett, Westerville, OH (US)

(21) Appl. No.: 19/301,772

(22) Filed: Aug. 15, 2025

Related U.S. Application Data
(60) Provisional application No. 63/683,906, filed on Aug. 16, 2024.

(51) Int. Cl. B23K 3/02; B23K 101/42; H05K 3/34

(52) U.S. Cl. CPC B23K 3/025; B23K 3/027; B23K 2101/42; H05K 3/34; H05K 2203/01

(57) ABSTRACT

In an embodiment, a soldering tip is configured for a number of solder pads at a number of radial locations and includes a soldering head, a shank, and a number of soldering feet. The soldering head is made of a thermally-conductive, corrosion-resistant material. The soldering head defines an upper head surface and a curved forward extension, the curved forward extension descending from the upper surface. The curved forward extension is lengthwise convexly curved and defines an extension face obverse to the upper head surface. The shank is coupled to the upper head surface of the soldering head and is configured to operatively couple with a soldering iron. The shank is made of a thermally conductive material. The soldering feet are operatively coupled to and protrude from the extension face. The soldering feet are configured to transfer bonding energy to the corresponding solder pads.

### CROSS REFERENCE TO RELATED PATENT APPLICATIONS

This application claims the benefit of U.S. Provisional Application No. 63/683,906, filed on Aug. 16, 2024, and entitled “RADIAL MULTI-POINT SOLDER TIP AND RELATED SOLDER DEVICE,” which is incorporated herein by reference in its entirety.

### BACKGROUND

A wire comb is a small component that facilitates the positioning of a number (e.g., two or more) of wires for soldering. Wire combs and soldering tips or fixtures can be used in combination in manufacturing. More recently, wire combs have been included as small plastic components that attach to a printed circuit board (“PCB”) to mount individual wires from multi-wire cables onto PCBs. These wire combs are mounted adjacent one or more ends of a PCB to permit the individual wires to be spaced apart yet held in place during a soldering, over-molding, or other process while permitting connecting the wires to the appropriate connections on the circuit board. After undergoing the appropriate soldering processes, the PCB and the wire comb are but two components in a finished PCB assembly (“PCBA”).

### BRIEF DESCRIPTION OF THE DRAWINGS

The Detailed Description is described with reference to the accompanying figures.

FIG. 1 is a side, isometric view of a multipoint radial solder tip, in accordance with an example embodiment of the present disclosure;

FIG. 2 is a bottom, isometric view of the multipoint radial solder tip, as shown in FIG. 1;

FIG. 3 is an isometric view of a wire comb and printed circuit board assembly (“PCBA”) combination for processing with the aid of a pair of multipoint radial solder tips, as shown in FIGS. 1 and 2, in an example embodiment of the present disclosure;

FIG. 4 is an isometric view of a cable with a series of wires for bonding to a number of solder pads on a PCBA (as shown in FIG. 3), in an example embodiment of the present disclosure; and

FIG. 5A is a block diagram, and FIG. 5B is a schematic view, of a soldering apparatus or unit, in an example embodiment of the present disclosure.

### DETAILED DESCRIPTION

Aspects of the disclosure are described more fully hereinafter with reference to the accompanying drawings, which form a part hereof, and which show, by way of illustration, example features. The features can, however, be embodied in many different forms and should not be construed as limited to the combinations set forth herein; rather, these combinations are provided so that this disclosure will be thorough and complete, and will fully convey the scope. The following detailed description is, therefore, not to be taken in a limiting sense.

### Introduction

U.S. patent application Ser. No. 17/890,413 (the contents of which are incorporated by reference thereto), also assigned to Vertiv, is directed to a wire comb. The wire comb includes a flat body which includes a first end and a second end. The ends are connected by an arcuate section which has an upper and lower surface. The upper surface of the arcuate section has a wire mount area that includes at least one opening formed in the upper surface with each opening including a shape selected to receive and hold a wire within. A mounting feature extends from at least one of the first end and the second end. The mounting feature is adapted to engage a printed circuit board. That application is further directed to a circuit board assembly. The circuit board assembly includes a printed circuit board (“PCB”) that has an upper and a lower surface, opposing ends, and side edges. The circuit board assembly also includes a wire comb which is mounted on the upper surface of the PCB and also is mounted proximate to an end of the PCB. These wire combs are mounted adjacent one or more ends of a PCB in order to permit the individual wires to be spaced apart yet held in place during a soldering, over-molding or other process while permitting connecting the wires to the appropriate connections on the circuit board. After undergoing the appropriate soldering processes, the PCB and the wire comb are but two components in a finished PCB assembly (“PCBA”).

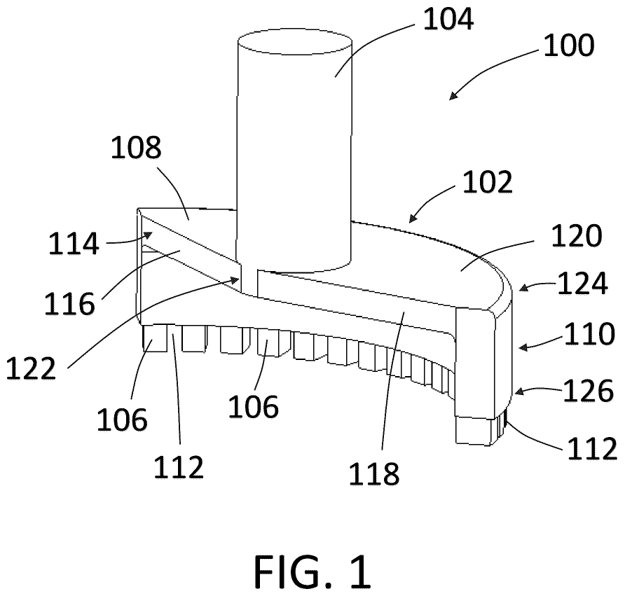

Currently, soldering wires directly to a PCBA can require a skilled workforce and can be time consuming. The present system (as shown collectively in FIGS. 1-4), in one embodiment thereof, can provide a radial solder pad pattern for PCB layouts to simplify and control the length of individual conductors in a cable and their attachment (soldering) to a PCBA. The present system can reduce the time and effort by soldering multiple, radially-spaced leads at a single time rather than individually (e.g., one at a time). The multipoint radial soldering tip of the present system can allow the parallel soldering of multiple leads to a PCBA, greatly reducing the time and increasing joint quality. The radial pattern of a given soldering tip/fixture to be employed can vary in diameter, curvature depending on the number and/or position of the solder pads required.

The present multipoint radial soldering tip can provide major cost savings. The cost savings may be generated by reducing the manufacturing time and increasing the quality of the soldering joints. In an embodiment, the soldering process may be robot-controlled for faster speed, better temperature control, and/or more accurate positioning.

### Description of Example Embodiments

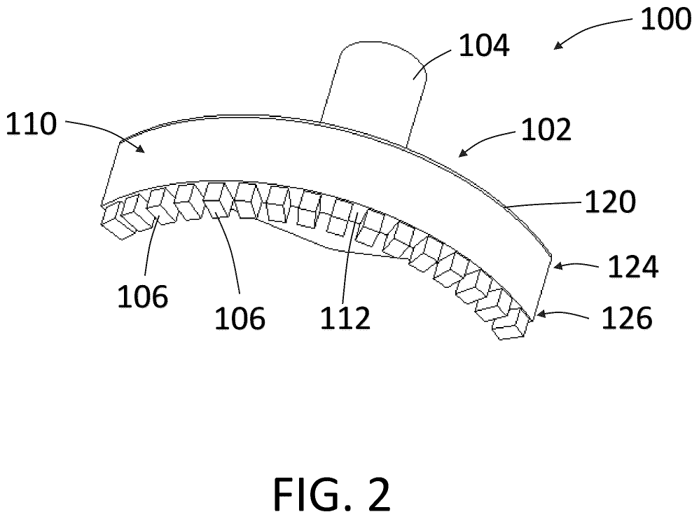

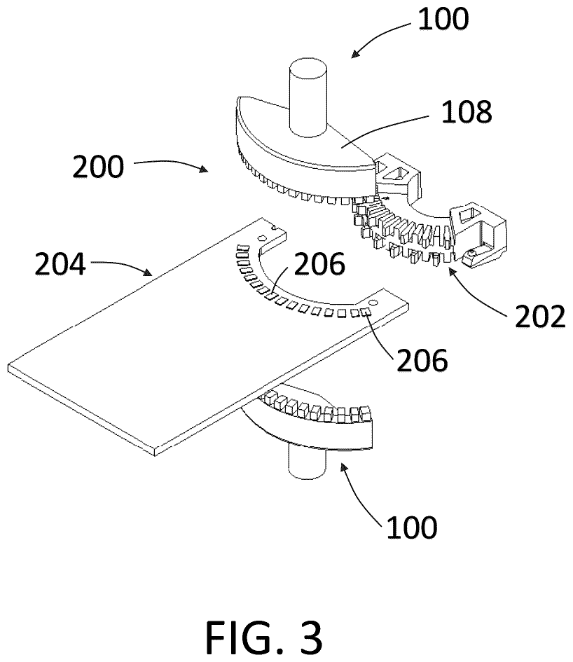

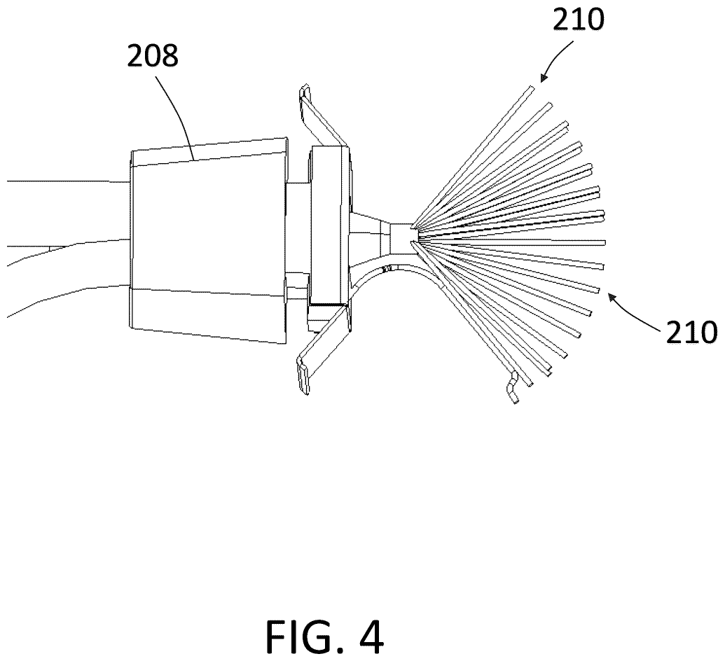

FIGS. 1-2 illustrate a multipoint radial soldering tip 100 (also referred to herein as a soldering tip or solder tip 100), in accordance with an example embodiment of the present disclosure. The soldering tip 100 can include a soldering head 102, a shank 104, and a number (e.g., two or more) of soldering feet 106. FIGS. 3 and 4 together illustrate a soldering system 200 utilizing a pair of the soldering tips 100, in accordance with an example embodiment of the present disclosure. It is to be understood than the soldering tip 100 may also be called a soldering fixture within the context of the present disclosure. The soldering system 200, in addition to the pair of soldering tips 100, includes a wire comb 202 and a printed circuit board assembly (“PCBA”) 204 (also known simply as a circuit board) carrying a number (e.g., two or more) of radially-spaced (as described subsequently) solder pads 206, as shown in FIG. 3. The soldering system 200 can include a cable 208, as shown in FIG. 4, supplying a number (e.g., two or more) of wires 210 for bonding to the solder pads 206 of FIG. 3.

The soldering head 102 of the soldering tip 100 can be made of a thermally conductive and corrosion resistant material, such as copper, a copper alloy, an iron-plated copper-based material, or another suitable material. The soldering head 102 can be configured to transfer soldering/bonding energy from a soldering iron (as described subsequently) to specific soldering/bonding locations (e.g., respective wire 210 and solder pad 206 positions). The soldering head 102 can define an upper head surface 108 and a curved forward extension 110, the curved forward extension 110 descending from the upper head surface 108. The curved forward extension 110 can be lengthwise convexly curved (i.e., curving convexly outward from the upper head surface 108, as seen from FIGS. 1 and 2) and may also be referred to as a convex forward extension or as a convex band, within the context of the present disclosure. In an embodiment, the curved forward extension can be perpendicular to the upper head surface 108 while also convexly descending therefrom. The curved forward extension 110 can define an extension face 112 obverse to the upper head surface 108. In an embodiment, the curved forward extension 110 defines an arcuate shape. In an embodiment, the arcuate shape is less than 180° in radial expanse; 135° or less in radial expanse; or 120° or less in radial expanse.

The soldering feet 106 can be mechanically and thermally coupled to and protrude from the extension face 112 of the curved forward extension 110. The soldering feet 106 can be configured to transfer bonding energy (e.g., heat and/or ultrasound) to the respective solder pads 206. The soldering feet 106, as part of the soldering head 102, can be made of a similarly thermal conductive and corrosion resistant material as the rest of the soldering head 102. It is to be understood that the soldering feet 106 can be co-formed and/or co-molded with the rest of the soldering head 102 (e.g., formed integrally therewith). In an embodiment, the soldering feet 106 can initially be integrally formed with the soldering head 102, but such soldering feet 106 may be replaced upon wear (e.g., replacement soldering feet 106 may be metallurgically and/or mechanically attached, as needed, thereby extending the lifetime of a given soldering head 102). In an embodiment, the soldering feet 106 may be separately formed and attached (e.g., metallurgically-welded, brazed, etc.; and/or mechanically), facilitating replacement thereof, given that the soldering feet 106 may wear out before the rest of the soldering head 102.

The respective soldering feet 106 can be radially spaced from one another along the arcuate shape defined by the curved forward extension 110. A number and a corresponding radial location of the respective soldering feet 106 can correspond to a number and a radial location of a number (e.g., two or more) of solder pads 206 at which a number (e.g., two or more) of corresponding wires 210 can be attached to a PCBA 204. In an embodiment, soldering tip 100 can includes at least three or four soldering feet 106. In an embodiment, the number of soldering feet 106 is at least 10. By including the soldering feet 106, the soldering tip 100 can be configured to solder in parallel at a number (e.g., two or more) of locations of solder pads 206 via the soldering feet 106. The soldering tip 100 can be more particularly configured to solder, in parallel, a number (e.g., two or more) of wires 210 to a PCBA 204 at a set of radial locations of solder pads 206, with the positioning of the wires 210 oriented by the wire comb 202.

The soldering head 102 can further define a head shelf 114, with the upper head surface 108 particularly defined by the head shelf 114. The shank 104 can be coupled (e.g., permanently or removably affixed) to the head shelf 114 of the soldering head 102, with the curved forward extension 110 descending from the head shelf 114. The head shelf 114 can define a first flaring shelf edge 116, a second flaring shelf edge 118, and a curved outer shelf edge 120 (also known as a curved shelf edge and/or a convex outer shelf edge), the head shelf 114 effectively having a “pie slice” shape. The first flaring shelf edge 116 and the second flaring shelf edge 118 can converge to form a shelf taper 122. The shank 104 can be operatively coupled to the head shelf 114 proximate to the shelf taper 122. Mounting of the shank 104 proximate to the shelf taper 122 can facilitate the placement of similar pressure/force on each of the soldering feet 106.

Further, the first flaring shelf edge 116 and the second flaring shelf edge 118 can connect with the curved shelf edge 120 (e.g., the convex outer shelf edge) opposite the shelf taper 122. In an embodiment, below and/or from that curved shelf edge 120 (e.g., proximate thereto), the curved forward extension 110 (e.g., the convex band) can descend from the head shelf 114 and, thus, below the upper head surface 108. The curved forward extension 110 or convex band 110 can define an upper band portion 124 (e.g., upper extension portion) and an opposing lower band portion 126 (e.g., lower extension portion). The upper band portion 124 thermally and mechanically can be coupled to the head shelf 114 (also known as a shelf member) proximate to the convex outer shelf edge 120. Further, the lower band portion 126 can particularly define a band face 112 (e.g., extension face) obverse to the shelf member 114, the convex band 110 defining a band curvature. In an embodiment, the soldering feet 106 can be mechanically and thermally coupled to and protrude from the band face 112 of the lower band portion 126 along a length of the band curvature. In an embodiment, the convex outer shelf edge 120 and the convex band 110 both define an arcuate shape, the respective soldering feet 106 radially spaced from one another along the arcuate shape defined by the convex band 110. It is to be understood that where generally equivalent terms have been established for various components, such equivalent terms can be interchangeably used throughout the specification and be within the scope of the present disclosure, as evidenced by using like part numbering for such equivalencies.

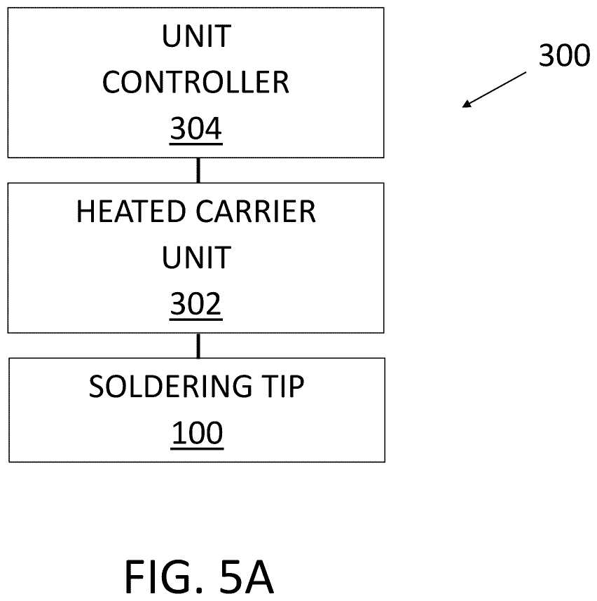

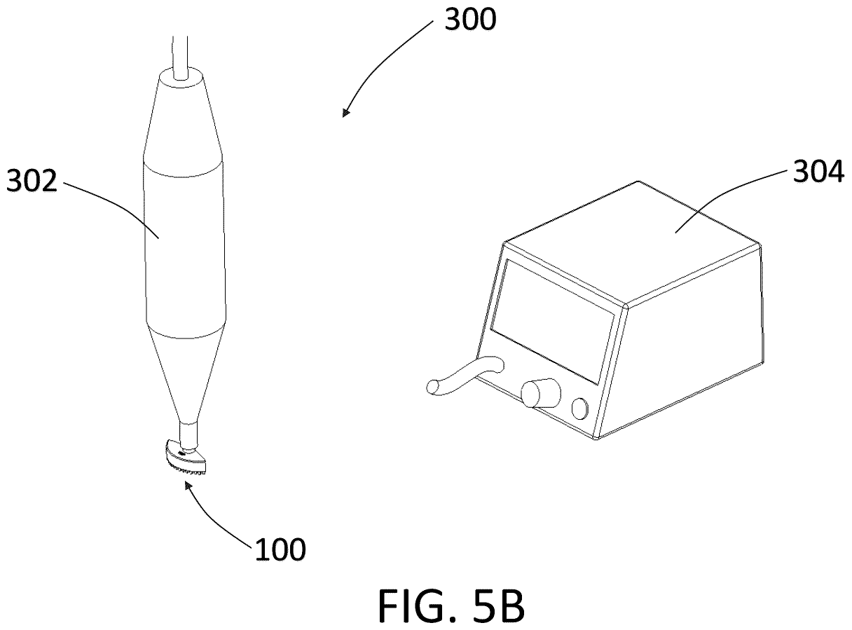

The soldering tip 100 can further include the shank 104. The shank 104 can be thermally and mechanically coupled to the shelf member 114 (e.g., head shelf) proximate to the shelf taper 122. The shank 104 can be configured to mechanically and thermally couple with a soldering iron (described and schematically later with reference to FIGS. 5A and 5B). The shank 104 can, for example, be screw-threaded, clamped, etc., with the soldering iron in a manner that facilitates sufficient bonding energy transfer (e.g., heat and/or ultrasound) therebetween, as well as a providing an adequate and stable mechanical connection therewith. The shank 104 can be made of a thermally conductive and mechanically durable material. The shank material may further be corrosion resistant, as well. In an embodiment, the shank 104 may be separate from or integral with the soldering head 102 (e.g., removably attached thereto; or permanently affixed or co-formed therewith).

FIGS. 5A and 5B illustrates a soldering unit 300 or soldering apparatus 300, in accordance with an example embodiment of the present disclosure, incorporating the multipoint radial soldering tip 100 of FIGS. 1-3. The soldering unit 300 can generally include the soldering tip 100 and a heated carrier unit 302 operatively coupled to the soldering tip 100. In an embodiment, the heated carrier unit 302 can be in the form of a soldering iron, as known in the art. The heated carrier unit 302, when, for example, in the form of a soldering iron, can include an extended carrier member and a heating element extending therethrough (not shown). The heated carrier unit 302 can be configured to convey bonding energy (e.g., heat and/or ultrasound) to the soldering tip 100 and to carry and facilitate the locating of the soldering tip 100. In an embodiment, the heated carrier unit 302 is mechanically couplable with the soldering tip 100, thereby allowing it to be able to carry and locate the soldering tip 100.

The soldering unit 300 can further include a unit controller 304 operatively coupled with the heated carrier unit 302. At a minimum, the unit controller 304 is configured to control the supply of bonding energy, for example, in the form of heat and/or ultrasound, to the soldering tip 100, via the heated carrier unit 302, and to facilitate movement and/or placement of the soldering tip 100 (e.g., manually and/or robotically). The unit controller 304 may further be a robotic control unit, thereby able to control the movement and/or placement of soldering tip 100, in addition to being configured to control the delivery of bonding energy to the soldering tip 100.

It is to be understood that the heated carrier unit 302 and unit controller 304 can be equipped with all the necessary componentry and functionality to be configured to operate in the manner described. For example, the heated carrier unit 302 can be equipped with the energy source(s) (e.g., heating elements and/or ultrasonic units), sensors (e.g., temperature and/or vibration), mechanical support, thermal/electrical conductors and insulators, as appropriate, and communication components needed to achieve the expected functionality, as known to one of ordinary skill in the art. Likewise, the unit controller 304 can include, for example, any processors, memory, displays, input devices, communication links, robotically-controlled actuation, etc., as needed to achieve the desired functionality, as known to one of ordinary skill in the art.

Those having skill in the art will recognize that the state of the art has progressed to the point where there is little distinction left between hardware and software implementations of aspects of systems; the use of hardware or software is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be implemented (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be implemented, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations will typically employ optically-oriented hardware, software, and or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link, etc.).

In a general sense, those skilled in the art will recognize that the various aspects described herein which can be implemented, individually and/or collectively, by a wide range of hardware, software, firmware, or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

Those having skill in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A soldering tip, comprising:
a soldering head defining an upper head surface and a curved forward extension, the curved forward extension descending from the upper head surface, the curved forward extension lengthwise convexly curved and defining an extension face obverse to the upper head surface; and
a plurality of soldering feet mechanically and thermally coupled to and protruding from the extension face of the curved forward extension.

2. The soldering tip of claim 1, wherein the curved forward extension defines an arcuate shape.

3. The soldering tip of claim 2, wherein the plurality of soldering feet are radially spaced from one another along the arcuate shape defined by the curved forward extension.

4. The soldering tip of claim 3, wherein a number and a corresponding radial location of the plurality of soldering feet correspond to a number and a radial location of a plurality of solder pads at which a plurality of corresponding wires is to be attached, and the plurality of solder feet are configured to transfer energy to the plurality of solder pads.

5. The soldering tip of claim 1, wherein the plurality of soldering feet includes at least four soldering feet.

6. The soldering tip of claim 1, wherein the soldering tip is configured to solder in parallel at a plurality of solder pad locations.

7. The soldering tip of claim 6, wherein the soldering tip is configured to solder, in parallel, a plurality of wires to a circuit board at the plurality of solder pad locations.

8. The soldering tip of claim 1, wherein the soldering head further defines a head shelf, the upper head surface defined by the head shelf, the curved forward extension descending from the head shelf.

9. The soldering tip of claim 8, wherein the head shelf defines a first flaring shelf edge, a second flaring shelf edge, and a curved shelf edge, the first flaring shelf edge and the second flaring shelf edge converging to form a shelf taper, the first flaring shelf edge and the second flaring shelf edge connecting with the curved shelf edge opposite the shelf taper, and;
the soldering tip further comprises a shank operatively coupled to the head shelf proximate to the shelf taper, the shank configured to mechanically and thermally couple with a soldering iron.

10. A soldering unit, comprising:
a soldering tip further comprising:
a soldering head defining an upper head surface and a curved forward extension, the curved forward extension descending from the upper surface, the curved forward extension lengthwise convexly curved and defining an extension face obverse to the upper head surface; and
a plurality of soldering feet mechanically and thermally coupled to and protruding from the extension face of the curved forward extension; and
a heated carrier unit operatively coupled to the soldering tip.

11. The soldering unit of claim 10, wherein the heated carrier unit is configured to convey bonding energy to the soldering tip, and comprises at least one of an extended carrier member and a heating element mechanically couplable to the soldering tip.

12. The soldering unit of claim 10, wherein the heated carrier unit is carried and controlled by a robotic unit.

13. The soldering unit of claim 10, wherein the curved forward extension defines an arcuate shape.

14. The soldering unit of claim 13, wherein the plurality of soldering feet are radially spaced from one another along the arcuate shape defined by the curved forward extension.

15. The soldering unit of claim 14, wherein a number and a corresponding radial location of the plurality of soldering feet correspond to a number and a radial location of a plurality of solder pads at which a plurality of corresponding wires is to be attached, and the plurality of solder feet are configured to transfer energy to the plurality of solder pads.

16. The soldering unit of claim 10, wherein the soldering tip is configured to solder in parallel at a plurality of solder pad locations.

17. A soldering tip, comprising:
a soldering head comprising:
a shelf member defining a shelf taper and an opposed convex outer shelf edge; and
a convex band descending from the shelf member proximate to the convex outer shelf edge, the convex band defining an upper band portion and an opposing lower band portion, the upper band portion thermally and mechanically coupled to the shelf member proximate to the convex outer shelf edge, the lower band portion defining a band face obverse to the shelf member, the convex band defining a band curvature;
a plurality of soldering feet mechanically and thermally coupled to and protruding from the band face of the lower band portion along a length of the band curvature.

18. The soldering tip of claim 17, wherein the convex outer shelf edge and the convex band both define an arcuate shape, the plurality of soldering feet radially spaced from one another along the arcuate shape defined by the convex band.

19. The soldering tip of claim 18, wherein a number and a corresponding radial location of the plurality of soldering feet correspond to a number and a radial location of a plurality of solder pads at which a plurality of corresponding wires is to be attached, and the plurality of solder feet are configured to transfer bonding energy to the plurality of solder pads.

20. The soldering tip of claim 17, wherein the soldering tip is configured to solder in parallel at a plurality of solder pad locations.
